(19) United States
(12) Patent Application Publication
(10) Pub. No.: US 2024/0254415 A1
(43) Pub. Date: Aug. 1, 2024

(54) Surface Treatment Compositions and Methods

(71) Applicant: Fujifilm Electronic Materials U.S.A., Inc., N. Kingstown, RI (US)

(72) Inventors: William A. Wojtczak, Mesa, AZ (US); Kazutaka Takahashi, Gilbert, AZ (US)

(21) Appl. No.: 18/419,639

(22) Filed: Jan. 23, 2024

Related U.S. Application Data
(60) Provisional application No. 63/441,854, filed on Jan. 30, 2023.

(51) Int. Cl. C11D 7/50; C11D 7/24; C11D 7/26; C11D 7/32; H01L 21/02

(52) U.S. Cl. CPC C11D 7/5013; C11D 7/245; C11D 7/261; C11D 7/264; C11D 7/265; C11D 7/267; C11D 7/32; C11D 7/3281; C11D 7/5022; H01L 21/02057

(57) ABSTRACT

This disclosure relates to methods and compositions for treating a semiconductor substrate having a pattern disposed on a surface of the substrate.

### CROSS-REFERENCE TO RELATED APPLICATION

The present application claims priority to U.S. Provisional Application Ser. No. 63/441,854, filed on Jan. 30, 2023, the contents of which are hereby incorporated by reference in their entirety.

### FIELD OF THE DISCLOSURE

The present disclosure relates generally to surface treatment, as well as related compositions and methods.

### BACKGROUND OF THE DISCLOSURE

At sub-20 nm critical dimensions, pattern collapse of FinFET's and dielectric stacks during wet clean and drying has become a major problem in semiconductor manufacturing processes. The conventional theory of pattern collapse implicates high capillary forces during rinse and dry as major contributors leading to the collapse phenomenon. However, other chemical and substrate properties may play an important role as well, namely, liquid surface tension and viscosity, substrate mechanical strength, pattern density and aspect ratio, and cleaner chemistry damage to substrate surfaces.

### SUMMARY OF THE DISCLOSURE

It has been found surprisingly that sublimable compounds capable of forming certain crystal structures can be particularly effective in minimizing pattern collapse on a patterned semiconductor substrate during a semiconductor manufacturing process, especially when the patterned structure on the substrate has a certain prevailing pattern geometry.

In one aspect, this disclosure features a method of treating a substrate, the method including: a) applying a surface treatment composition to a substrate having a pattern disposed on a surface thereof, wherein the surface treatment composition includes at least one sublimable compound and at least one solvent, the pattern includes a repeating structure, the repeating structure has a two-dimensional symmetry selected from the group consisting of C4, D1, D2, and D4 rosette groups, and the at least one sublimable compound is capable of forming a crystal having a crystal system that is not a cubic or tetragonal crystal system; b) solidifying the surface treatment composition on the surface; and c) removing by sublimation the sublimable compound disposed on the surface.

In another aspect, this disclosure features a method of treating a substrate, the method including: a) applying a surface treatment composition to a substrate having a pattern disposed on a surface thereof, wherein the surface treatment composition includes at least one sublimable compound and at least one solvent, and the at least one sublimable compound includes 1,4-diazabicyclo[2,2,2]octane, cyclotene, 1H-pyrazole, piperazine, acetoxime, hexachloroethane, nitrosobenzene, or hexamethylcyclotrisiloxane; b) solidifying the surface treatment composition on the surface; and c) removing by sublimation the sublimable compound disposed on the surface.

In another aspect, this disclosure features a method of treating a substrate, the method including: a) applying a surface treatment composition to a substrate having a pattern disposed on a surface thereof, wherein the surface treatment composition includes at least one sublimable compound and at least one solvent, the pattern includes a repeating structure, the repeating structure has a square or rectangular two-dimensional symmetry, and the at least one sublimable compound is capable forming a crystal having a crystal system that is not a cubic or tetragonal crystal system; b) solidifying the surface treatment composition on the surface; and c) removing by sublimation the sublimable compound disposed on the surface.

In still another aspect, this disclosure features a surface treatment composition that includes (1) at least one sublimable compound including 1,4-diazabicyclo[2,2,2]octane, cyclotene, 1H-pyrazole, piperazine, acetoxime, hexachloroethane, nitrosobenzene, or hexamethylcyclotrisiloxane, the at least one sublimable compound being in an amount of from about 1% to about 20% by weight of the surface treatment composition; and (2) a solvent in an amount of from about 80 wt % to about 99 wt % of the surface treatment composition.

Other features, objects, and advantages of the invention will be apparent from the description and the claims.

### DETAILED DESCRIPTION OF THE DISCLOSURE

As defined herein, unless otherwise noted, all percentages expressed should be understood to be percentages by weight to the total weight of a composition. Unless otherwise noted, the properties mentioned here are measured at atmospheric pressure. The term “solvent” mentioned herein, unless otherwise noted, refers to a single solvent or a combination of two or more (e.g., three or four) solvents. In the present disclosure, “ppm” means “parts-per-million”, “ppb” means “parts-per-billion” and “ppt” means “parts-per-trillion”.

In general, this disclosure relates to surface treatment compositions and methods. The surface treatment compositions described herein generally include at least one (e.g., two or three) sublimable compound, which can be a liquid or a solid at 25° C. In some embodiments, the sublimable compound is the component in the surface treat compositions that can be sublimed in the surface treatment methods described herein. Without wishing to be bound by theory, it is believed that surface treatment compositions containing a sublimable compound described herein can be used to clean a patterned substrate, while minimize pattern collapse that typically occurs in a traditional cleaning process (e.g., by rinsing and drying a patterned substrate).

In some embodiments, the sublimable compound is capable of forming a crystal having a crystal system that is not a cubic or tetragonal crystal system among the seven well-known crystal systems (i.e., triclinic, monoclinic, orthorhombic, tetragonal, trigonal, hexagonal, and cubic crystal systems). In some embodiments, the sublimable compound is capable of forming a crystal having a hexagonal, trigonal, monoclinic, triclinic, or orthorhombic crystal system among the seven crystal systems. Without wishing to be bound by theory, it is believed that a sublimable compound capable of forming the above crystal structure can minimize pattern collapse when used to clean a pattern on a semiconductor that includes a repeating structure having a two-dimensional symmetry selected from the group consisting of C4, D1, D2, and D4 rosette groups or having a square or rectangular two-dimensional symmetry.

In some embodiments, the sublimable compound is capable of forming a crystal having a cubic or tetragonal crystal system. Without wishing to be bound by theory, it is believed that such a sublimable compound can minimize pattern collapse when used to clean a pattern on a semiconductor that includes a repeating structure having a two-dimensional symmetry that does not belong to C4, D1, D2, and D4 rosette groups or having no two-dimensional symmetry).

In some embodiments, the sublimable compound can have a melting point of at least about 20° C. (e.g., at least about 25° C., at least about 30° C., at least about 35° C., at least about 40° C., at least about 45° C., at least about 50° C., at least about 55° C., or at least about 60° C.) and/or at most about 100° ° C. (e.g., at most about 95° C., at most about 90° C., at most about 85° C., at most about 80° C., at most about 75° C., at most about 70° C., at most about 65° C., or at most about 60° C.) under atmospheric pressure. Without wishing to be bound by theory, it is believed that a compound having such a melting point can be suitable for sublimation.

In some embodiments, the sublimable compound can have a vapor pressure of at least about 0.1 mm Hg (e.g., at least about 0.5 mm Hg, at least about 1 mm Hg, at least about 2 mm Hg, at least about 3 mm Hg, at least about 4 mm Hg, or at least about 5 mm Hg) and/or at most about 10 mm Hg (e.g., at most about 9 mm Hg, at most about 8 mm Hg, at most about 7 mm Hg, at most about 6 mm Hg, or at most about 5 mm Hg) at 25° C. Without wishing to be bound by theory, it is believed that a compound having a vapor pressure lower than about 0.1 mm Hg at 25° C. cannot be sublimed easily. Further, without wishing to be bound by theory, it is believed that a compound having a vapor pressure higher than about 10 mm Hg at 25° C. evaporates too easily and may not stay on a surface of a semiconductor substrate for a period sufficient to treat the surface.

In some embodiments, the sublimable compound or the surface treatment composition containing the sublimable compound can have a surface tension of at least about 15 mN/m (e.g., at least about 20 mN/m, at least about 25 mN/m, or at least about 30 mN/m) and/or at most about 65 mN/m (e.g., at most about 60 mN/m, at most about 55 mN/m, at most about 50 mN/m, at most about 45 mN/m, at most about 40 mN/m, or at most about 35 mN/m) at 25° C. Without wishing to be bound by theory, it is believed that, in some embodiments, a compound or composition having a surface tension in the above range can form a surface having a relatively large water contact angle (e.g., at least about 50 degrees) and reduce pattern collapse.

In some embodiments, the surface treatment composition containing the sublimable compound can have a viscosity of at least about 0.5 centistokes (e.g., at least about 0.6 centistokes, at least about 0.8 centistokes, at least about 1 centistoke, at least about 1.2 centistokes, at least about 1.4 centistokes, at least about 1.6 centistokes, at least about 1.8 centistokes, or at least about 2 centistokes) and/or at most about 5 centistokes (e.g., at most about 4.8 centistokes, at most about 4.6 centistokes, at most about 4.5 centistoke, at most about 4.4 centistokes, at most about 4.2 centistokes, at most about 4 centistokes, at most about 3.5 centistokes, or at most about 3 centistokes) at 25° C.

In some embodiments, the sublimable compound, solvent, and/or additive (e.g., a surface modification agent or a catalyst) described herein is highly pure. In some embodiments, the purity of the sublimable compound, solvent, and/or additive is at least about 99.9% (e.g., at least about 99.99% or at least about 99.999%) or 100%. In some embodiments, a sublimable compound or a surface treatment composition described herein can have a total metal content of 0 to 1 ppb (e.g., 0 to 500 ppt or 0 to 300 ppt) in mass. In some embodiments, the total number of the particles having a size of 0.1 μm or more in a sublimable compound or a surface treatment composition described herein is at most 200 (e.g., at most 150, at most 100, at most 80, at most 60, or at most 50) per 1 ml of the sublimable compound. The number of “particles” in a liquid medium can be counted by a light scattering type in-liquid particle counter and is referred as LPC (liquid particle count).

In some embodiments, the sublimable compound described herein does not have any substantial volume change during the phase change from liquid to solid upon freezing, which can reduce pattern collapse or damage. In some embodiments, during sublimation, the sublimable compound can be removed uniformly without the need of any subsequent rinsing or drying, which can further reduce pattern collapse or damage.

In general, the sublimable compound described herein can have at least one (e.g., two, three, or all) of the properties described above. Examples of suitable sublimable compounds include 1,4-diazabicyclo[2,2,2]octane, cyclotene, 1H-pyrazole, piperazine, acetoxime, hexachloroethane, nitrosobenzene, hexamethylcyclotrisiloxane, and cyclohexanone oxime.

The crystal structures that can be formed from exemplary sublimable compounds described herein are included in Table 1 below.

TABLE 1

| Crystal System | Sublimable compounds |
|---|---|
| Triclinic | cyclotene |
| Monoclinic | piperazine |
| Orthorhombic | 1H-pyrazole, hexachloroethane, nitrosobenzene |
| Hexagonal | 1,4-diazabicyclo[2,2,2]octane, acetoxime, |
| | cyclohexanone oxime |
| Trigonal | hexamethylcyclotrisiloxane |

Certain properties of exemplary sublimating compounds described herein are included in Table 2 below.

TABLE 2

| | Vapor | Freezing/ |
|---|---|---|
| | Pressure | Melting |
| | at 25° C. | Point |
| Sublimating Compound | (mm Hg) | (° C.) |
| 1,4-diazabicyclo[2,2,2]octane | 1.2 | 156-159 |
| cyclotene | 0.49 | 104-108 |
| 1H-pyrazole | 0.9 | 66-68 |
| piperazine | 0.16 | 106 |
| acetoxime | 1.8 | 61 |
| hexachloroethane | 0.2 (20° C.) | 183-185 |
| nitrosobenzene | 0.28 | 64-67 |
| hexamethylcyclotrisiloxane | 9.8 | 64-66 |
| cyclohexanone oxime | 0.09 | 88-91 |

In some embodiment, a sublimable compound described herein is also a surface modification agent (e.g., having surface modification functions such as forming a hydrophobic layer (e.g., a hydrophobic monolayer) on a semiconductor substrate surface to reduce pattern collapse during a rinsing or drying process). Examples of such sublimating compounds include Si-containing compounds such as hexamethylcyclotrisiloxane.

In some embodiments, the sublimable compound is in an amount of from at least about 1 wt % (e.g., at least about 2 wt %, at least about 3 wt %, at least about 4 wt %, at least about 5 wt %, at least about 6 wt %, at least about 7 wt %, at least about 8 wt %, at least about 9 wt %, or at least about 10 wt %) to at most about 20 wt % (e.g., at most about 19 wt %, at most about 18 wt %, at most about 17 wt %, at least about 16 wt %, at most about 15 wt %, at most about 14 wt %, at most about 13 wt %, at most about 12 wt %, at most about 11 wt %, or at most about 10 wt %) by weight of surface treatment compositions described herein.

In some embodiments, the surface treatment compositions described herein can optionally further include at least one (e.g., two or three) solvent (e.g., an organic solvent). For example, the solvent can be selected from the group consisting of alcohols (e.g., isopropyl alcohol and ethanol), amides (e.g., dimethylacetamide), ketones (e.g., methylisobutylketone and acetone), ethers (e.g., tetrahydrofuran and dipropylether), esters (e.g., n-butyl acetate and propylene glycol methyl ether acetate (PGMEA)), carbonate esters (e.g., dimethyl carbonate), alkanes (e.g., heptane and octane), cycloalkanes (e.g., cyclohexane), aromatics (e.g., toluene), and water. In such embodiments, the surface treatment method described herein can further include a solvent evaporation step to remove the solvent before removing the sublimable compound by sublimation.

In some embodiments, the solvent can have a vapor pressure of at least about 0.1 mm Hg (e.g., at least about 0.5 mm Hg, at least about 1 mm Hg, at least about 2 mm Hg, at least about 3 mm Hg, at least about 4 mm Hg, or at least about 5 mm Hg) and/or at most about 10 mm Hg (e.g., at most about 9 mm Hg, at most about 8 mm Hg, at most about 7 mm Hg, at most about 6 mm Hg, or at most about 5 mm Hg) at 25° C.

In some embodiments, the solvent is in an amount of from at least about 80 wt % (e.g., at least about 82 wt %, at least about 84 wt %, at least about 85 wt %, at least about 86 wt %, at least about 88 wt %, at least about 90 wt %, at least about 92 wt %, at least about 94 wt %, or at least about 95 wt %) to at most about 99 wt % (e.g., at most about 98 wt %, at most about 96 wt %, at most about 95 wt %, or at most about 90 wt %) of the surface treatment compositions described herein.

Certain properties of exemplary solvents described herein are included in Table 3 below.

TABLE 3

| | Vapor | | Freezing/ | Surface |
|---|---|---|---|---|
| | Pressure | Viscosity at | Melting | Tension |
| | at 25° C. | 25° C. | Point | at 25° C. |
| Solvent | (mm Hg) | (Centistokes) | (° C.) | (mN/m) |
| isopropyl alcohol | 33.1 | 2.6 | −89 | 21.4 |
| n-Butyl acetate | 11.5 | 0.83 | −74 | 25.1 (20° C.) |
| dimethyl carbonate | 50 | 0.58 | 3 | 28.5 |
| toluene | 28.5 | 0.65 | −94.9 | 27.8 |
| PGMEA | 2.8 | 1.1 | −66 | 26.9 |

In some embodiments, the surface treatment compositions described herein can optionally further include at least one (e.g., two or three) surface modification agent. Without wishing to be bound by theory, it is believed that a surface treatment composition containing the surface modification agent can have an improved sublimation drying process compared to a surface treatment composition without the surface modification agent and can further reduce pattern collapse when cleaning a patterned semiconductor substrate. In some embodiments, when the sublimable compound in the surface treatment compositions itself is a surface modification agent, the surface treatment compositions can include no additional surface modification agents.

In some embodiments, the surface modification agent can include a Si-containing compound. In some embodiments, the Si-containing compound can be a disilazane. For example, the disilazane can be hexamethyldisilazane, heptamethyldisilazane, N-methyl hexamethyldisilazane, 1,3-diphenyltetramethyldisilazane, or 1,1,3,3-tetraphenyl-1,3-dimethyldisilazane.

In some embodiments, the Si-containing compound can include a trimethylsilyl group. For example, the Si-containing compound can be trimethylsilyltriflate, N-(trimethylsilyl)dimethylamine, N-(trimethylsilyl)diethylamine, 4-trimethylsilyloxy-3-penten-2-one, bis(trimethylsilyl)sulfate, methoxytrimethylsilane, ethoxytrimethylsilane, N-allyl-N,N-bis(trimethylsilyl)amine, N-(trimethylsilyl)diethylamine, N,N-bis(trimethylsilyl) urea, trimethylsilanol, N-(trimethylsilyl)acetamide, or tris(trimethylsilyl)phosphate.

In some embodiments, the Si-containing compound can be an aminosilane. For example, the aminosilane can be triisopropyl(dimethylamino)silane. In some embodiments, the Si-containing compound can be a siloxane. A siloxane compound can be a disiloxane, an oligosiloxane, a cyclosilxoane, or a polysiloxane. As used herein, the term “oligosiloxane” refers to a compound having 3-6 siloxane units, and the term “polysiloxane” refers to a compound having more than 6 siloxane units. Examples of suitable siloxanes include octamethylcyclotetrasiloxane or 1,3-bis(heptadecafluoro-1,1,2,2-tetrahydrodecyl)tetramethyldisiloxane.

Certain properties of exemplary surface modification agents described herein are included in Table 4 below.

TABLE 4

| | Vapor | Viscosity | Freezing/ | Surface | Both Surface |
|---|---|---|---|---|---|
| | Pressure | at 25° C. | Melting | Tension at | Modification |
| | at 25° C. | (Centi- | Point | 25° C. | and |
| Surface Modifying Agent | (mm Hg) | stokes) | (° C.) | (mN/m) | Sublimation |
| Trimethylsilyltriflate | 14 | NA | <0 | 22 (est.) | |
| Hexamethyldisilazane | 13.8 | 0.9 | −78 | 18.2 | |
| Trimethylsilyldimethylamine | 67.9 | NA | <0 | NA | |
| Ethoxytrimethyl silane | 111 (22° C.) | NA | −83 | 16.7 | |
| Octamethylcyclotetrasiloxane | 1.0 | 2.3 | 18 | 18.4 | Yes |
| Trimethylsilanol | 15.8 | 4.9 | −4.5; −12; | 18.4 | Yes |
| | | | 9.5 | | |
| T-Hexyldimethylcholorosilane | 1 (est.) | NA | 14 | 21.6 (est.) | Yes |
| 1,3-Bis(heptadecafluoro-1,1,2,2- | <1 | NA | 0 to −5 | 16.4 | Yes |
| tetrahydrodecyl)tetramethyldisiloxane | | | | | |
| Triisoporopyldimethylaminosilane | 0.06 | NA | 27-30 | NA | Yes |
| N-(trimethylsilyl)acetamide | 0.5 | NA | 46-49 | NA | Yes |
| Tris(trimethylsilyl)Phosphate | <1 | | 2-4 | 19.5(20° C.) | Yes |

In some embodiments, the surface modification agent is in an amount of from at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.5 wt %, at least about 2 wt %, or at least about 2.5 wt %) to at most about 5 wt % (e.g., at most about 4 wt %, at most about 3 wt %, at most about 2 wt %, or at most about 1 wt %) of the surface treatment compositions described herein.

In some embodiments, the surface treatment compositions described herein can optionally further include at least one (e.g., two or three) catalyst. For example, the catalyst can be triflic acid, triflic anhydride, methanesulfonic acid, acetic acid, or acetic anhydride. In some embodiments, the catalyst is in an amount of from at least about 0.1 wt % (e.g., at least about 0.2 wt %, at least about 0.3 wt %, at least about 0.4 wt %, at least about 0.5 wt %, at least about 0.8 wt %, at least about 1 wt %, at least about 2 wt %, or at least about 3 wt %) to about at most about 10 wt % (e.g., at most about 9 wt %, at most about 8 wt %, at most about 7 wt %, at most about 6 wt %, or at most about 5 wt %) of the surface treatment compositions described herein. Without wishing to be bound by theory, it is believed that the catalyst can facilitate reaction between the surface modification agent and a reactive group (e.g., a silanol group) in the semiconductor substrate surface, thereby improving surface treatment of the surface treatment compositions.

Certain properties of exemplary catalysts described herein are included in Table 5 below.

TABLE 5

| | Vapor | Viscosity | Freezing/ | Surface |
|---|---|---|---|---|
| | Pressure at | at | Melting | Tension at |
| | 25° C. | 25° C. | Point | 25° C. |
| Catalyst | (mm Hg) | (Centistokes) | (° C.) | (mN/m) |
| Triflic Acid | 8 | 1.69 | −40 | 35.6 (est.) |
| Triflic Anhydride | 8 (20° C.) | NA | −80 | 34.1 |
| Methanesulfonic acid | 0.08 (80° C.) | 7.9 | 17-19 | 53.4 |
| Acetic acid | 15 | 1.34 (15° C.) | 16.5 | 28 (20° C.) |
| Acetic anhydride | 5.1 | 0.88 (15° C.) | −73.1 | 31.9 |

In some embodiments, the surface treatment compositions described herein can include only two types of components, i.e., (1) at least one sublimable compound and (2) at least one solvent. In some embodiments, the surface treatment compositions described herein can include only three types of components, i.e., (1) at least one sublimable compound, (2) at least one solvent, and (3) at least one surface modification agent. In some embodiments, the surface treatment compositions described herein can include only four types of components, i.e., (1) at least one sublimable compound, (2) at least one solvent, (3) at least one surface modification agent, and (4) at least one catalyst.

Without wishing to be bound by theory, it is believed that, in some embodiments, the surface treatment compositions described herein can form a surface treatment layer (e.g., a hydrophobic layer such as a hydrophobic monolayer) on a patterned surface of a semiconductor substrate such that the patterned surface has a water contact angle of at least about 50 degrees (e.g., at least about 55 degrees, at least about 60 degrees, at least about 65 degrees, at least about 70 degrees, at least about 75 degrees, at least about 80 degrees, at least about 85 degrees, at least about 89 degrees, at least about 90 degrees, at least about 95 degrees, or at least about 100 degrees) and/or at most about 175 degrees. Without wishing to be bound by theory, it is believed that such a surface treatment layer can improve the sublimation drying process and facilitate prevention or reduction of the collapse of the patterned features (e.g., having a dimension of at most about 20 nm) on a semiconductor substrate surface during a subsequent semiconductor manufacturing process after the surface is treated by the surface treatment compositions described herein.

In some embodiments, the surface treatment compositions described herein can specifically exclude or be substantially free of one or more of additive components, in any combination, if more than one. Such additive components are selected from the group consisting of non-aromatic hydrocarbons, protic solvents (e.g., alcohols or amides), lactones (e.g., those with 5- or 6-membered rings), propylene glycol methyl ether acetate, Si-containing compounds (e.g., siloxanes such as disiloxanes; silanes such as alkoxysilanes; silazanes such as disilazanes, cyclic silazanes or heterocyclic silazanes; and those having a Si—H group or an aminosilyl group), polymers, oxygen scavengers, quaternary ammonium compounds including quaternary ammonium hydroxides or salts, amines, bases (such as alkaline bases (e.g., NaOH, KOH, LiOH, Mg(OH)₂, and Ca(OH)₂) and organic bases), surfactants, defoamers, fluorine-containing compounds (e.g., HF, H₂SiF₆, H₂PF₆, HBF₄, NH₄F, and tetraalkylammonium fluoride), nitrogen-containing compounds, oxidizing agents (e.g., peroxides, hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, ammonium persulfate, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, urea hydrogen peroxide, and peracetic acid), abrasives, silicates, hydroxycarboxylic acids, carboxylic and polycarboxylic acids (e.g., those lacking amino groups), cyclic compounds (e.g., cyclic compounds containing at least two rings, such as substituted or unsubstituted naphthalenes, or substituted or unsubstituted biphenylethers), chelating agents (e.g., azoles, diazoles, triazoles, or tetrazoles), corrosion inhibitors (such as azole or non-azole corrosion inhibitors), buffering agents, guanidine, guanidine salts, pyrrolidone, polyvinyl pyrrolidone, metal salts (e.g., metal halides), and metal-containing catalysts.

In some embodiments, the surface treatment compositions described herein (which include at least one sublimable compound and optionally one or more other components) have relatively low metal and particle contents. In some embodiments, the surface treatment compositions can have a total metal content of 0 to 1 ppb (e.g., 0 to 500 ppt or 0 to 300 ppt) in mass. In some embodiments, the total number of the particles having a size of 0.1 μm or more in a surface treatment composition described herein is at most 200 (e.g., at most 150, at most 100, at most 80, at most 60, or at most 50) per 1 ml of the surface treatment composition.

In some embodiment, the surface treatment methods described herein can be performed, for example, by a) applying a surface treatment composition (e.g., containing at least one sublimable compound) to a substrate (e.g., a semiconductor substrate) having a pattern formed or disposed on a surface thereof; b) solidifying the surface treatment composition on the surface; and d) removing by sublimation the sublimable compound disposed on the surface. In some embodiments, the surface treatment composition can form a surface treatment layer (e.g., a hydrophobic monolayer) on the surface of the substrate to reduce pattern collapse (e.g., by forming a surface having a water contact angle of at least about 50 degrees).

In some embodiments, the pattern on a semiconductor substrate to be treated can include a repeating structure. In some embodiments, the repeating structure can have a two-dimensional (2D) symmetry selected from the group consisting of C4, D1, D2, and D4 rosette groups or a cubic or rectangular 2D symmetry. In some embodiments, the 2D symmetry can be the symmetry in the 2D surface supporting the pattern. In some embodiments, the repeating structure can have at least one (e.g., two or three) dimension (e.g., a length, a width, and/or a depth) of at most about 100 nm (e.g., at most about 90 nm, at most about 80 nm, at most about 70 nm, at most about 60 nm, at most about 50 nm, at most about 40 nm, at most about 30 nm, or at most about 20 nm) and/or at least about 1 nm (e.g., at least about 2 nm or at least about 5 nm). In some embodiments, the pattern can have a feature (e.g., a non-repeating structure) having the above dimensions.

In some embodiments, semiconductor substrate that can be treated by the surface treatment compositions described herein can be constructed by at least one material selected from the group consisting of silicon, silicon germanium, silicon nitride, copper, Group III-V compounds such as GaAs, and any combination thereof. In some embodiments, the semiconductor substrate can be a silicon wafer, a copper wafer, a silicon dioxide wafer, a silicon nitride wafer, a silicon oxynitride wafer, a carbon doped silicon oxide wafer, a SiGe wafer, or a GaAs wafer. The semiconductor substrate can additionally contain exposed integrated circuit structures such as interconnect features (e.g., metal lines and dielectric materials) on its surfaces. Metals and metal alloys used for interconnect features include, but are not limited to, aluminum, aluminum alloyed with copper, copper, titanium, tantalum, cobalt, nickel, silicon, polysilicon, titanium nitride, tantalum nitride, tin, tungsten, SnAg, SnAg/Ni, CuNiSn, CuCoCu, and/or CoSn. The semiconductor substrate can also contain layers of interlayer dielectrics, silicon oxide, silicon nitride, titanium nitride, silicon carbide, silicon oxide carbide, silicon oxide nitride, titanium oxide, and/or carbon doped silicon oxides.

In some embodiments, the semiconductor substrate surface to be treated by the surface treatment compositions described herein includes features containing SiO₂, Al₂O₃, SiN, TiN, TiO₂, SiOC, SiON, Si, SiGe, Ge, and/or W. In some embodiments, the substrate semiconductor surface includes features containing SiO₂ and/or SiN.

In general, the semiconductor substrate surface to be treated by the surface treatment compositions described herein includes patterns formed by a prior semiconductor manufacturing process (e.g., a lithographic process including applying a photoresist layer, exposing the photoresist layer to an actinic radiation, developing the photoresist layer, etching the semiconductor substrate beneath the photoresist layer, and/or removing the photoresist layer).

In some embodiments, the surface treatment methods described herein can optionally further include contacting the surface of a substrate with at least one aqueous cleaning solution before contacting the surface with a surface treatment composition described herein. In such embodiments, the at least one aqueous cleaning solution can include water, an alcohol, aqueous ammonium hydroxide, aqueous hydrochloric acid, aqueous hydrogen peroxide, an organic solvent, or a combination thereof.

In some embodiments, the surface treatment methods described herein can optionally further include contacting the surface of a substrate with a first rinsing solution (e.g., ozonated water, water, an organic solvent such as isopropanol, or a combination thereof) after contacting the surface with the at least one aqueous cleaning solution but before contacting the surface with the surface treatment composition described herein. In some embodiments, the surface treatment methods described herein can optionally further include contacting the surface with a second rinsing solution (e.g., water, an organic solvent such as isopropanol, or a combination thereof) after contacting the surface with the surface treatment composition described herein. In some embodiments, the surface treatment methods described herein can optionally further include drying the surface (e.g., after any of the steps of contacting the surface with first rinsing solution, the surface treatment composition described herein, or the second rinsing solution). In some embodiments, the surface treatment methods described herein can further include removing the surface treatment layer, if any, from the surface.

In some embodiments, this disclosure provides methods for cleaning a semiconductor substrate (e.g., a wafer) having a pattern formed or disposed on a surface of the substrate. Such methods can be performed, for example, by:
a) optionally, contacting the surface with an aqueous cleaning solution;
b) optionally, contacting the surface with a first rinsing solution;
c) contacting the surface with a surface treatment composition described herein, in which the surface treatment composition includes at least one sublimable compound;
d) maintaining the surface treatment composition on the surface for a time sufficient to modify the surface;
e) optionally removing any solvent (if present) on the surface;
f) solidifying the surface treatment composition on the surface;
g) removing by sublimation the sublimable compound disposed on the surface (which can optionally form a surface treatment layer).
   In such embodiments, the pattern on the semiconductor substrate surface can include a feature having a dimension of at most about 20 nm. In some embodiments, the above methods do not include a subsequent rinsing and/or drying after the sublimation step.

In step a) of the above described methods, the substrate (e.g., a wafer) bearing a patterned surface can optionally be treated with one or more aqueous cleaning solutions. When the patterned surface is treated with two or more aqueous cleaning solutions, the cleaning solutions can be applied sequentially. The aqueous cleaning solutions can be water alone, an organic solvent alone, or can be solutions containing water, a solute, and optionally an organic solvent. In some embodiments, the aqueous cleaning solutions can include water, an alcohol (e.g., a water soluble alcohol such as isopropanol), an aqueous ammonium hydroxide solution, an aqueous hydrochloric acid solution, an aqueous hydrogen peroxide solution, an organic solvent (e.g., a water soluble organic solvent), or a combination thereof.

In step b), the cleaning solution from step a) can be optionally rinsed away using a first rinsing solution. The first rinsing solution can include water, an organic solvent (e.g., isopropanol), or an aqueous solution containing an organic solvent. In some embodiments, the first rinsing solution is at least partially miscible with the cleaning solution used in step a). In some embodiments, step b) can be omitted when the cleaning solution used in step a) is not moisture sensitive or does not contain any appreciable amount of water. In some embodiments, step (b) can be used in the absence of step a).

In step c), the substrate surface can be treated with a surface treatment composition described herein, which can optionally form a modified surface having a surface treatment layer (e.g., a hydrophobic layer). A semiconductor substrate can be contacted with the surface treatment composition by any suitable method, such as placing the surface treatment composition into a tank and immersing and/or submerging the semiconductor substrate into the surface treatment composition, spraying the surface treatment composition onto the semiconductor substrate, streaming the surface treatment composition onto the semiconductor substrate, or any combinations thereof. In some embodiments, this step can be performed at a temperature of about 20-35° C. In some embodiments, the surface treatment composition can be pre-processed by using ion exchange, distillation, sublimation and/or filtration processes to meet the ultrapure material requirements for this process.

In step d), the surface treatment composition can be maintained on the surface for a period of time ranging from about 10 seconds to about 300 seconds to clean and/or modify the surface.

In step e), when the surface treatment composition includes a solvent, the solvent can be removed (e.g., by evaporation) before sublimation of the sublimable compound. In some embodiments, the solvent can be removed by evaporation, such as by heating the semiconductor substrate with a heating means such as a hotplate or infrared lamp, by placing the semiconductor substrate in vacuum (e.g., in a chamber), or both. In some embodiments, when the surface treatment composition includes a solvent, solvent saturation and blanketing gas (N₂, clean dry air, etc.) for the tool tank (which holds the sublimable compound) and chamber can be used to modulate evaporation for the purpose of preventing micro and nano bubble “bumping”, which can result in pattern substrate defects during the solvent removal process. It is believed that this additional process can improve sublimation process uniformity and provide a better static friction free drying process and minimize substrate defectivity.

In step f), the remaining surface treatment composition (e.g., containing a sublimable compound) can be solidified by lowering the temperature of the semiconductor substrate such as cooling the backside of the semiconductor substrate or cooling the chamber in which the semiconductor substrate is placed. The temperature to solidify or freeze the surface treatment composition or the sublimable compound can be at most about 15° C. (e.g., at most about 10° C., at most about 5° C., at most about 0° C., at most about −5° C., at most about −10° C., or at most about −20° C.) or at least about −30° C. In some embodiments, when a sublimable compound having a melting point at least about 18ºC is used, it may be necessary to use heating jacket for dispense canister and transfer lines to prevent premature fluid solidification on transfer of the sublimable compound to the substrate. In such embodiments, the sublimable compound can be solidified at ambient temperature.

In step g), the sublimable compound can be sublimed by increasing the substrate temperature, reducing substrate chamber pressure (e.g., after placing the substrate in a chamber), or both to achieve an acceptable condition for uniform sublimation based on the phase diagram of the sublimable compound. In some embodiments, an inline endpoint detector can be used to verify completion of the sublimation process. The pressure and temperature of the substrate chamber can then be slowly brought to standard temperature and pressure (STP) conditions under nitrogen gas flow. The substrate can then be removed from the substrate chamber. Cycles of increasing temperature (with N₂ flow) and/or reducing pressure can then be used to clean the chamber and remove any trace amounts of the sublimable compound from chamber. Without wishing to be bound by theory, it is believed that this sublimation step can minimize pattern collapse on the semiconductor substrate (e.g., by eliminating the subsequent rinsing and/or drying steps).

The semiconductor substrate having a cleaned, patterned surface prepared by the methods described herein can be further processed to form one or more circuits on the substrate or can be processed to form into a semiconductor device (e.g., an integrated circuit device such as a semiconductor chip) by, for example, assembling (e.g., dicing and bonding) and packaging (e.g., chip sealing).

In some embodiments, this disclosure features articles (e.g., an intermediate semiconductor article formed during the manufacturing of a semiconductor device) that includes a semiconductor substrate, and a surface treatment composition described herein supported by the semiconductor substrate.

The present disclosure is illustrated in more detail with reference to the following examples, which are for illustrative purposes and should not be construed as limiting the scope of the present disclosure.

### EXAMPLES

### Example 1

A patterned substrate having a square 2D symmetry was cleaned using RCA clean sequence (dilute hydrofluoric acid/ammonium hydrogen peroxide/hydrogen peroxide and hydrochloric acid), and rinsed with water, isopropanol or other rinse or combination of rinses using a single wafer tool (SWT) processor equipped with substrate spinning, temperature control, and chemistry dispense. The substrate was maintained with a liquid on the surface prior to surface modification and sublimation to prevent stiction drying.

Surface treatment compositions (i.e., formulations examples 1-9 (FE-1 to FE-9) and comparative formulations 1-5 (CFE-1 to CFE-5)) were prepared by mixing the components at room temperature. The compositions of these formulations are summarized in Table 6 below. All percentages listed in Table 6 are weight percentages, unless indicated otherwise.

TABLE 6

| | | | Surface | | Average | |
|---|---|---|---|---|---|---|
| | Sublimable | Crystal | Modification | | Uncollapsed | Standard |
| Form. # | Compound | Family | Agent | Solvent | Pattern (%) | Deviation |
| FE-1 | 5% DABCO | Hexagonal | None | 95% IPA | 55.2 | 32.7 |
| FE-2 | 5% Cyclotene | Triclinic | None | 95% IPA | 91 | 18 |
| FE-3 | 5% Cyclotene | Triclinic | None | 95% DMC | 91 | 9.8 |
| FE-4 | 5% 1H- | Orthorhombic | None | 95% DMC | 90.8 | 1.7 |
| | Pyrazole | | | | | |
| FE-5 | 5% 1H- | Orthorhombic | None | 95% toluene | 52.7 | 4.2 |
| | Pyrazole | | | | | |
| FE-6 | 5% 1H- | Orthorhombic | 1% HMDS | 94% DMC | 94.12 | 2.9 |
| | Pyrazole | | | | | |
| FE-7 | 5% 1H- | Orthorhombic | 3% HMDS | 92% DMC | 95.56 | 2.3 |
| | Pyrazole | | | | | |
| FE-8 | 4% CHO | Hexagonal | None | 96% IPA | 86.1 | 5.4 |
| FE-9 | 4% CHO | Hexagonal | 1% HMDS | 95% IPA | 86.6 | 4 |
| CFE-1 | 5% | Cubic, | None | 95% NBA | 7.2 | 1.7 |
| | Adamantane | Tetragonal | | | | |
| CFE-2 | 5% 1H- | Orthorhombic | None | 95% NBA | 6.1 | 0.9 |
| | Pyrazole | | | | | |
| CFE-3 | 5% 1H- | Orthorhombic | None | 95% IPA | 35.2 | 30.3 |
| | Pyrazole | | | | | |
| CFE-4 | 5% DABCO | Hexagonal | None | 95% NBA | 6.9 | 1.8 |
| CFE-5 | 5% 1,3,5- | Trigonal | None | 95% IPA | 4.6 | 1.1 |
| | Trioxane | | | | | |

DABCO = 1,4-Diazabicyclo[2.2.2]octane
CHO = Cyclohexanone oxime
HMDS = Hexamethyldisilazane
IPA = Isopropyl alcohol
DMC = Dimethyl Carbonate
NBA = N-Butyl acetate

As shown in Table 6, all of formulations FE-1 to FE-9 (which contained a sublimable compound capable of forming a hexagonal, triclinic, or orthorhombic crystal structure) surprisingly exhibited superior patter collapse results when they were used to clean a patterned substrate having a square 2D symmetry. By contrast, comparative formulation CFE-1 included a compound capable of forming a cubic and/or tetragonal crystal structure and resulted in a relatively large amount of pattern collapse when it was used to clean a patterned substrate having a square 2D symmetry. Without wishing to be bound by theory, it is believed that, although 1H-pyrazole and 1,4-diazabicyclo[2.2.2]octane in formulations CFE-2 to CFE-4 were respectively capable of forming orthorhombic and hexagonal crystal structures, the solvents used in these formulations may have changed the crystallization behavior of these sublimable compounds and reduced their abilities in preventing pattern collapse. Lastly, without wishing to be bound by theory, it is believed that, although 1,3,5-trioxane in formulation CFE-5 was capable of forming a trigonal crystal structure, 1,3,5-trioxane has a relatively high vapor pressure (i.e., 17 mm Hg at 25° C.) and evaporates too easily to be effective in preventing pattern collapse.

### Example 2

Formulation FE-6 described in Example 1 was used to treat the following three types of wafers: (1) silicon wafers pretreated with diluted hydrofluoric acid (dHF), (2) silicon oxide wafers, and (3) silicon nitride wafers. Subsequently, the treated wafers were not rinsed, rinsed with deionized water, or rinsed with isopropanol.

The coupons were placed on the AST VCA 3000 Contact Angle Tool and the following procedure was performed to measure the contact angles:
1. Place the SiO₂, SiN or Si coupon onto the stage.
2. Raise the stage upward by rotating Vertical Knob clockwise until the specimen is just below the needle.
3. Dispense a drop of de-ionized water, lightly touching the specimen surface, then lower the specimen until the droplet separates from the needle tip.
4. Center the drop across the field-of-view using transverse knob for stage adjustment.
5. Focus the drop in field-of-view to get a sharp image by moving the stage along guide rails.
6. Click the “AutoFAST” button to freeze the image and calculate. Two numbers will be displayed; these are the left and right contact angles.
7. To calculate manually, use the mouse to place five markers around the droplet.
8. Select the droplet icon from the Main Menu to calculate the contact angle.
9. This will create a curve fit and tangent lines on the image. Two numbers will be displayed in the left-hand-corner of the screen; these are the left and right contact angles.
10. Repeat above procedure at 3 substrate sites and average the resulting contact angles. The measurement results are summarized in Table 7 below.

TABLE 7
Contact angle (°) of water droplet

| Post | | | | | | |
|---|---|---|---|---|---|---|
| process | | | | | | Standard |
| rinse | Wafer | 1^{st} | 2^{nd} | 3^{rd} | Average | Deviation |
| No rinse | Si (dHF | 87.2 | 88.5 | 89.7 | 88.47 | 1.25 |
| | pretreated) | | | | | |
| | SiO | 83.6 | 84.2 | 81.3 | 83.03 | 1.53 |
| | SiN | 78.2 | 82.5 | 79.2 | 79.97 | 2.25 |
| DI water | Si (dHF | 83.8 | 87.6 | 82 | 84.47 | 2.85 |
| rinse | pretreated) | | | | | |
| | SiO | 86.7 | 86.2 | 84.3 | 85.73 | 1.27 |
| | SiN | 82.9 | 86.5 | 84.3 | 84.57 | 1.81 |
| IPA rinse | Si (dHF | 86.7 | 88.4 | 87.5 | 87.53 | 0.85 |
| | pretreated) | | | | | |
| | SiO | 83.7 | 85.5 | 84.6 | 84.6 | 0.9 |
| | SiN | 83.6 | 85.2 | 86.4 | 85.07 | 1.4 |

As shown in Table 7 above, all wafers treated by FE-6 exhibited water contact angles close to 90°, which suggests that their surface was modified by the surface modification agent (i.e., HMDS) in FE-6.

While the invention has been described in detail with reference to certain embodiments thereof, it will be understood that modifications and variations are within the spirit and scope of that which is described and claimed.

What is claimed is:

1. A method of treating a substrate, comprising:
a) applying a surface treatment composition to a substrate having a pattern disposed on a surface thereof, wherein the surface treatment composition comprises at least one sublimable compound and at least one solvent, the pattern comprises a repeating structure, the repeating structure has a two-dimensional symmetry selected from the group consisting of C4, D1, D2, and D4 rosette groups, and the at least one sublimable compound is capable of forming a crystal having a crystal system that is not a cubic or tetragonal crystal system;
b) solidifying the surface treatment composition on the surface; and
c) removing by sublimation the sublimable compound disposed on the surface.

2. The method of claim 1, wherein the repeating structure has a length or width of at most about 100 nm.

3. The method of claim 1, wherein the at least one sublimable compound has a vapor pressure of from about 0.1 mm Hg to about 10 mm Hg at 25ºC.

4. The method of claim 1, wherein the at least one sublimable compound has a melting point of from about 20° C. to about 100° C.

5. The method of claim 1, wherein the at least one sublimable compound is capable of forming a crystal having a hexagonal, trigonal, monoclinic, triclinic, or orthorhombic crystal system.

6. The method of claim 1, wherein the repeating structure has a square pattern on the surface.

7. The method of claim 1, wherein the at least one sublimable compound comprises 1,4-diazabicyclo[2,2,2]octane, cyclotene, 1H-pyrazole, piperazine, acetoxime, hexachloroethane, nitrosobenzene, hexamethylcyclotrisiloxane, or cyclohexanone oxime.

8. The method of claim 1, wherein the at least one sublimable compound is in an amount of from about 1% to about 20% by weight of the surface treatment composition.

9. The method of claim 1, wherein the at least one solvent has a vapor pressure of from about 0.1 mm Hg to about 10 mm Hg at 25ºC.

10. The method of claim 1, wherein the at least one solvent is selected from the group consisting of alcohols, amides, ketones, ethers, esters, carbonate esters, alkanes, cycloalkanes, aromatics, and water.

11. The method of claim 1, wherein the at least one solvent is in an amount of from about 80 wt % to about 99 wt % of the surface treatment composition.

12. The method of claim 1, wherein the surface treatment composition further comprises at least one surface modification agent.

13. The method of claim 12, wherein the at least one surface modification agent comprises a Si-containing compound.

14. The method of claim 12, wherein the at least one surface modification agent Is from about 0.1 wt % to about 5 wt % of the surface treatment composition.

15. The method of claim 1, wherein the surface comprises SiO₂, Al₂O₃, SiN, TIN, TiO₂, SiOC, SiON, Si, SiGe, Ge, or W.

16. A method of treating a substrate, comprising:
a) applying a surface treatment composition to a substrate having a pattern disposed on a surface thereof, wherein the surface treatment composition comprises at least one sublimable compound and at least one solvent, and the at least one sublimable compound comprises 1,4-diazabicyclo[2,2,2]octane, cyclotene, 1H-pyrazole, piperazine, acetoxime, hexachloroethane, nitrosobenzene, or hexamethylcyclotrisiloxane;
b) solidifying the surface treatment composition on the surface; and
c) removing by sublimation the sublimable compound disposed on the surface.

17. The method of claim 16, wherein the at least one sublimable compound is in an amount of from about 1% to about 20% by weight of the surface treatment composition.

18. The method of claim 16, wherein the at least one solvent is selected from the group consisting of alcohols, amides, ketones, ethers, esters, carbonate esters, alkanes, cycloalkanes, aromatics, and water.

19. The method of claim 16, wherein the at least one solvent is in an amount of from about 80 wt % to about 99 wt % of the surface treatment composition.

20. The method of claim 16, wherein the surface comprises SiO₂, Al₂O₃, SiN, TIN, TiO₂, SiOC, SION, Si, SiGe, Ge, or W.

21. A method of treating a substrate, comprising:
a) applying a surface treatment composition to a substrate having a pattern disposed on a surface thereof, wherein the surface treatment composition comprises at least one sublimable compound and at least one solvent, the pattern comprises a repeating structure, the repeating structure has a square or rectangular two-dimensional symmetry, and the at least one sublimable compound is capable forming a crystal having a crystal system that is not a cubic or tetragonal crystal system;
b) solidifying the surface treatment composition on the surface; and
c) removing by sublimation the sublimable compound disposed on the surface.

22. A surface treatment composition, comprising:
at least one sublimable compound comprising 1,4-diazabicyclo[2,2,2]octane, cyclotene, 1H-pyrazole, piperazine, acetoxime, hexachloroethane, nitrosobenzene, or hexamethylcyclotrisiloxane, the at least one sublimable compound being in an amount of from about 1% to about 20% by weight of the surface treatment composition; and
a solvent in an amount of from about 80 wt % to about 99 wt % of the surface treatment composition.

23. The composition of claim 22, wherein the at least one solvent is selected from the group consisting of alcohols, amides, ketones, ethers, esters, carbonate esters, alkanes, cycloalkanes, aromatics, and water.
